(19) United States
(12) Patent Application Publication
(10) Pub. No.: US 2003/0076154 A1
(43) Pub. Date: Apr. 24, 2003

(54) Controlling circuit power consumption through supply voltage control

(76) Inventors: Kaveh Shakeri, Atlanta, GA (US); James D. Meindl, Marietta, GA (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/272,925

(22) Filed: Oct. 17, 2002

Related U.S. Application Data
(60) Provisional application No. 60/329,873, filed on Oct. 17, 2001.

(51) Int. Cl. H03K 3/01

(52) U.S. Cl. 327/534

(57) ABSTRACT

Embodiments of the present invention provide systems and methods for reducing circuit power consumption by adjusting the supply voltage to the circuit. A preferred embodiment of such a method can be generally described as a method comprising the following steps: detecting a temperature change at the circuit; and adjusting a supply voltage to the circuit such that the power consumption is controlled. On the other hand, one embodiment of a system for reducing the power consumption of a circuit can be implemented with a device having structure for detecting a temperature change at the circuit and for adjusting a supply voltage to the circuit responsive to said temperature change at the circuit.

### CROSS-REFERENCE TO RELATED APPLICATION

This application claims priority to copending U.S. provisional application entitled, “Dynamic Supply Voltage for Power Reduction,” having Serial No. 60/329,873, filed Oct. 17, 2001, which is entirely incorporated herein by reference.

### TECHNICAL FIELD

The present invention is generally related to the reduction of circuit power consumption and, more particularly, is related to systems and methods for reducing power consumption of digital circuits by adjusting the supply voltage of the circuit.

### BACKGROUND OF THE INVENTION

Electronic systems and circuits form the basis of many devices upon which people depend. For example, electronic technologies such as digital computers, calculators, audio devices, video equipment, and telephone systems are common in many homes and offices. Such electronic systems are often implemented by or through semiconductor devices.

A semiconductor device, generally, may be thought of as an electronic device that makes use of semiconductor material. In essence some of the electronic technologies implemented in such devices use semiconductor materials to build the electronic technologies. Semiconductor materials are basically materials that have an electric resistance that is somewhere between a pure conductor (such as copper wire) and an insulator (such as plastic); hence the name “semiconductor.” Silicon is a common semiconductor material employed extensively in modern electronic devices.

When a semiconductor material is used to construct electronic devices, the conductivity of the semiconductor material is often altered through a process known as “doping.” “Doping” involves the process of introducing impurities into the semiconductor. The impurity added to the semiconductor is called a “dopant.” Through “doping,” the conductivity of the semiconductor material can be controlled in a precise and predictable manner.

The process of “doping” places mobile, charged carriers for conducting electricity in the semiconductor crystal lattice. When semiconductor materials are “doped” so as to add negative charge carriers to the semiconductor lattice, the material is referred to as an “n-type” semiconductor. Conversely, when semiconductor materials are doped so as to add positive carriers to the semiconductor lattice, the material is then referred to as a “p-type” semiconductor.

One type of electronic device that implements semiconductor material is a transistor. One particular type of transistor is the field-effect transistor (“FET”). The FET gets its name from the way it physically operates. The mechanism that controls current through an FET is based upon an electric “field” established by a voltage applied to a particular portion of the FET.

A Metal-oxide semiconductor field-effect transistor (“MOSFET”) is a particular type of FET. As the name suggests, a MOSFET was traditionally made from growing a silicon dioxide layer on a semiconductor substrate and positioning a metal gate on the silicon dioxide layer. Thus, the MOSFET made use of a metal, an oxide, and a semiconductor to create a FET. Of course, now, MOSFETs are constructed in a variety of ways, not necessarily employing a metal gate.

FIG. 1A depicts a typical MOSFET device 10. This figure demonstrates the basic elements of a MOSFET 10 as it is most commonly constructed and implemented. As with any such device, it is possible to manufacture and/or implement a MOSFET in a variety of ways. The MOSFET 10 of FIG. 1A is merely one example of a MOSFET for demonstrative purposes only.

The most prominent portion of the MOSFET device 10 is a substrate, or “body” 12 of the device 10. Typically, the substrate 12 is a doped silicon material. The silicon of the body 12 may be either doped such as to be an n-type material, or a p-type material. Once the doped substrate 12 is prepared, two heavily doped regions 13, 14 are created in the substrate 12. One of these regions is typically called the “source” 13 and the other of the regions is typically called the “drain” 14. If the substrate silicon 12 is doped so as to be a p-type material, then the source 13 and drain 14 are usually doped to be n-type materials. A device configured in this manner is referred to as an “NFET” transistor. Conversely, if the substrate 12 is doped to be an n-type material, then the source 13 and drain 14 are doped so as to be p-type materials. A device configured in this manner is referred to as a “PFET” transistor.

An insulating layer 16, usually a silicon dioxide material, is grown onto a surface of the substrate 12 between the source 13 and the drain 14. Then, a metal material 17, or more commonly a polycrystalline silicon material, is deposited onto the insulating layer 16. This metal material 17 serves as what is known as a “gate electrode.” Metal contacts 18, 19 are also made to the source region 13 and the drain region 14, respectively. Additionally, a metal contact 21 is typically made to the substrate body 12 of the MOSFET 10. The body contact could be positioned in a number of different ways. As depicted in FIG. 1A, the body contact is what is known as an ohmic contact. The contact is connected to a portion of the body 20 that has been doped so as to be the same material as the substrate, only the doping is heavier than the substrate. This type of connection is common when the MOSFET is configured into an Integrated Circuit (“IC”) chip.

Terminals 22, 23, 24, and 26 are brought away from each of the metal contacts. Therefore, the typical MOSFET 10 has four terminals: a source terminal 22, a gate terminal 23, a drain terminal 24, and a body terminal 26.

As mentioned above, the MOSFET 10 depicted in FIG. 1A and described above is merely one typical implementation of a MOSFET device. There may be other configurations possible, as well as other terminal configurations and dopings. FIG. 1A is exemplary only.

As noted above, the FET portion of the MOSFET's name comes from the manner in which the device operates. The term “field-effect” in the name MOSFET is related to the application of an “electromotive field,” or voltage, to the gate terminal 23. Application of this voltage causes carriers, either electrons or “holes,” to gather in the region of the substrate 12 immediately under the insulating layer 16. Additionally, a capacitance across the insulating layer 16 is formed.

The carriers collecting in the substrate 12 form a conductive “channel” 27 through which current can flow from the source 13 to the drain 14, or vice versa. The amount of voltage applied to the gate terminal 23 controls the size of the conductive channel 27. Consequently, a gate voltage can be used to control the source-drain current through the channel 27 in a MOSFET 10.

There is a value of voltage applied to the gate terminal 23 that will induce a channel 27 and permit current to flow from source 13 to drain 14, or vice versa. At gate voltages below this value, only a very small current flows through the transistor. This current is called the “subthreshold current.” At gate voltages above this value, current may freely pass from source 13 to drain 14, or vice versa. This current can be referred to as the “on” current for the transistor. This value of gate voltage is known as the “threshold voltage.”

FIG. 1B depicts the circuit diagram symbols used to represent an NFET 28 and a PFET 29. The terminals of the MOSFETS are represented by the letters S, G, D, and B.

FIG. 2 depicts a circuit diagram of a typical configuration of a Complementary Metal Oxide Semiconductor (“CMOS”) circuit, or CMOS “gate” 30. The particular “gate” 30 depicted in FIG. 2 is a CMOS circuit known as a “NOT gate,” or a CMOS “inverter.” This CMOS circuit combines a PFET 34 and an NFET 33 in the manner indicated.

In this gate 30, the voltage applied to the gate terminals 31 of the NFET 33 and the PFET 34 of the CMOS inverter 30 may be considered a type of “input” voltage. The voltage at the drain terminals 32 of the NFET 33 and the PFET 34 of the CMOS inverter 30 may be considered an “output” voltage of the gate 30. If the voltage at the gate terminals 31 is set to a low level, such as zero or ground, then the output of this CMOS gate 30 will be a high voltage, such as the supply voltage. In essence, when the “input” voltage is zero, the NFET 33 of the “NOT gate” will be “off” such that only negligible drain current flows through the NFET 33. However, the PFET 34 will be “on” such that current, an “on-current” will flow from the source 36 to drain 37 of the PFET.

On the other hand, if the gate voltage is set to a high level, such as the supply voltage to the circuit, then the output of this CMOS gate 30 will be a low voltage, such as zero. In essence, when the “input” voltage is high, the PFET 34 of the “not gate” 30 will be “off” such that only negligible on-current flows through the PFET 34. However, the NFET 33 will be “on” such that drain current will flow between the NFET source 38 and the NFET drain 39.

As noted above, the current passing from the drain to the source when the gate voltage is larger than the threshold voltage is called the “on-current.” Generally, the on-current is related to the temperature of the circuit. As the circuit operates, its temperature naturally increases. Of course, the temperature of the circuit may also increase (or decrease) due to a change in the ambient temperature of the environment. Regardless of the source of the temperature increase (or decrease), as the temperature of the circuit increases, the on-current also changes.

At one particular value of supply voltage, the on-current is independent of the temperature. This voltage is know as the Zero-Temperature-Coefficient (“ZTC”) voltage of the circuit. At supply voltages below the ZTC voltage, the on-current has a positive relationship to the temperature change. That is, as temperature increases, on-current increases. However, at supply voltages above the ZTC voltage, as the temperature increases, the on-current decreases.

The ZTC voltage for most MOSFETs currently in use is about 1V, and therefore, circuits with power supply voltages below 1V have a positive temperature dependence of the on-current. Currently, it is typical for CMOS circuits to operate with supply voltages above 1V, that is, above the ZTC voltage. However, the International Technology Roadmap for Semiconductors (“ITRS”) has published data on the projected future of semiconductors. This data projects that by as early as 2004, CMOS circuits will be operating with supply voltages below 1V. The value of supply voltages used for CMOS circuits will likely continue to decrease in the years following 2004. Therefore, in the future, the supply voltage of CMOS circuits may be below the ZTC of the circuit such that as the temperature of the circuit increases, the on-current will also increase. As noted above, the temperature of a circuit may increase because of a number of different reasons. For example, the operation of the device may increase the temperature of the circuit, or the ambient temperature may either increase or reduce the temperature of the circuit.

An increase in on-current is typically desired. Increasing the on-current decreases the delay of the circuit, thereby typically making the circuit faster.

The on-current freely flows through a transistor, or circuit, when the gate voltage is above the threshold voltage of the transistor, or circuit. However, when the gate voltage is below the threshold voltage, there is still some current that flows through the circuit. This current is call the “subthreshold” drain current. It is typically desirable to minimize this current as it is basically a “leakage” current. This is typically an unwanted source of static power consumption by a circuit.

The total power consumption of a digital circuit is generally composed of three parts: the dynamic power consumption, the static power consumption, and the short circuit power consumption. The dynamic power consumption is largely due to dynamic charging and discharging of load capacitance in the circuit. The static power consumption, sometimes called the “leakage current power,” largely results from leaking diodes and transistors. Finally, the short circuit power consumption generally results from the flow of current from the supply to ground during the switching of the circuit.

The main contributor to static power consumption within future generations of circuits will likely be the subthreshold drain current, or “leakage” current. That is, the leakage current when the circuit is operating with a gate voltage below the threshold voltage will likely be the primary source of static power consumption. Additionally, as the temperature of a circuit increases, the subthreshold current, and therefore the static power consumption, should also increase. The subthreshold current is a function of temperature and increases as the temperature of a circuit increases. Unlike the on-current for a circuit, the relationship between temperature and the subthreshold drain current is not a function of the supply voltage. It is, of course, desirable to minimize static power consumption of a circuit.

Scaling the dimensions of MOSFETs is typically required in order to continue the trend toward reducing the power and increasing the speed of electronic devices. Although the power dissipation of a single gate may be reduced, the total power dissipation of a chip will likely be increased because of the increasing complexity of a chip. This makes it more difficult for the overall package to transfer this power to the environment.

On the other hand, to increase the speed of the chip, it is known that the threshold voltage should be reduced, which will increase the static power dissipation exponentially. Therefore, the static power dissipation will likely be a big fraction of the total power consumption of the chip in the future. As such, static power consumption will likely be an increasing fraction of the total power consumption of digital circuits in coming years.

Thus, a heretofore unaddressed need exists in the industry to reduce the static power consumption, and thus the total power consumed, by a circuit operating with supply voltages below the ZTC voltage.

### SUMMARY OF THE INVENTION

Embodiments of the present invention provide systems and methods for reducing circuit power consumption by adjusting the supply voltage to the circuit as the temperature of the circuit changes with time.

Briefly described, one embodiment of such a method, among others, can be broadly summarized by the following steps: detecting a temperature change at the circuit; and adjusting a supply voltage to the circuit such that the power consumption is controlled.

Briefly described, one embodiment of a system for controlling the power consumption of a circuit can be implemented with a device having structure for detecting a temperature change at the circuit and for adjusting a supply voltage to the circuit responsive to said temperature change at the circuit.

Other systems, methods, features, and advantages of the present invention will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1A is a cut-away side view of a typical MOSFET circuit.

FIG. 1B is circuit diagram of typical NFET and PFET type MOSFETs.

FIG. 2 is a circuit diagram of a CMOS “NOT gate,” or “inverter.”

FIG. 3A is a flow chart showing the steps employed by a control circuit for reducing the power consumption of a circuit by monitoring the circuit delay in order to detect a change in circuit temperature, according to a first preferred embodiment.

FIG. 3B is a continuation of the flow chart of FIG. 3A.

FIG. 4 is a flow chart showing the steps employed by a control circuit for reducing the power consumption of a circuit by monitoring the circuit temperature directly, according to a second preferred embodiment.

FIG. 5 is a plot of the normalized delay versus the temperature of an exemplary 70 nm CMOS circuit using the preferred system and method described herein.

FIG. 6 is a plot of the on-current versus the temperature of an exemplary 70 nm CMOS circuit using the preferred system and method described herein.

FIG. 7 is a plot of normalized total power consumption versus temperature of an exemplary 70 nm CMOS circuit using the preferred system and method described herein.

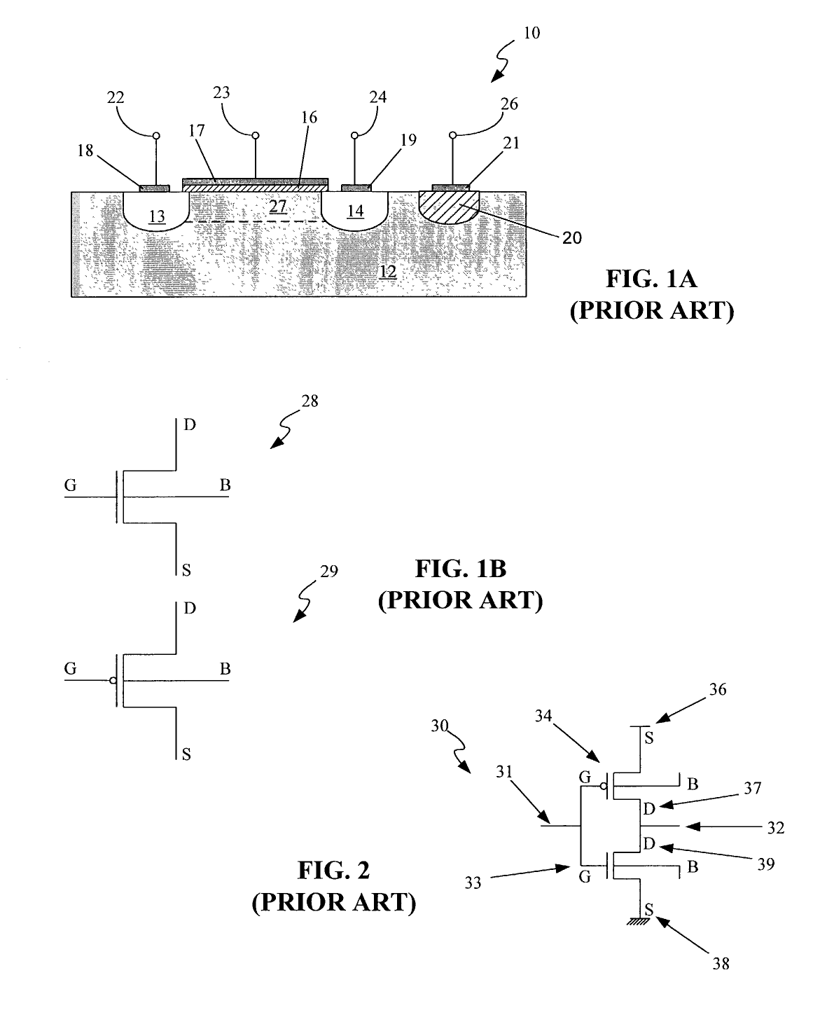

### DETAILED DESCRIPTION

Broadly described, the embodiments described herein comprise systems and methods for reducing power consumption of a circuit. Specifically, the systems and methods of the disclosed embodiments deal with reducing power consumption of digital circuits comprising MOSFETs. Furthermore, the systems and methods are particularly tailored to reduce power consumption of a circuit operating with supply voltages below the Zero-Temperature-Coefficient (“ZTC”) voltage of the circuit. Dynamic power, static power, and short circuit power are all reduced through using the systems and methods disclosed herein.

The systems and methods described herein are based upon observations about the way in which MOSFET transistors, and circuits comprising these transistors, operate with changing temperature. It has been realized that a change in the temperature of the circuit has ramifications to the operation of the circuit. These realizations, as seen below, can be utilized to reduce the static power consumption of a circuit.

Static Power Consumption Increases with Increasing Temperature

First, it can be demonstrated that the static power consumption of a MOSFET, or a circuit comprising MOSFETs, varies with temperature. Of course, as noted above, it is well known that the overall power consumption of a circuit is generally composed of the dynamic power consumption, the static power consumption, and the short circuit power consumption. Stated in a mathematical equation, the total power consumption of an individual CMOS gate, or an overall circuit comprised of MOSFETs, may be expressed as:

P=P_{dy}+Pₛₜ+P_{sc}, (1)

where P_{dy} is the dynamic power, Pₛₜ is the static power and P_{sc} is the short circuit power.

The static power consumption of an individual MOSFET, as noted above, is currently, or will likely be in the future, largely due to the leakage current of the transistor. Therefore, the static power consumption of a circuit may be expressed by the following relationship:

Pₛₜ=V_{dd}×I_{Leak}, (2)

where I_{Leak} is the leakage current of the MOSFET transistor and V_{dd} is the power supply voltage of the circuit.

Where most of the leakage current is subthreshold current, therefore, the equation for static power consumption may be expressed as:

Pₛₜ=V_{dd}×I_{Sub}, (3)

where I_{Sub} is the subthreshold current and V_{dd} is the power supply voltage applied to the circuit.

As is known, the subthreshold leakage current is a function of the temperature of a circuit. Or, in other words:

I_{sub}=ƒ(T). (4)

Therefore, from equation (3), the static power consumption of the circuit is also a function of the temperature of the circuit. Indeed, it is known that the subthreshold current of a circuit increases exponentially with temperature. Therefore, the static power consumption also increases exponentially with increasing temperature. Stated another way, the “worst-case” static power dissipation of a circuit occurs at the highest operating temperature of the circuit.

Mobility and Threshold Voltage Vary with Temperature

The next realization that contributes to the present systems and methods is that mobility and threshold voltage are two parameters of a MOSFET transistor, which also change with the changing temperature of the circuit. These relationships may be expressed as:

μ=ƒ(T), (5)

and

V_{TH}=ƒ(T), (6)

where μ is the mobility of the circuit and V_{TH} is the threshold voltage of the circuit.

It is also known that as the temperature of a circuit increases, the mobility of the circuit is reduced. Similarly, an increase in the temperature of a circuit, or a transistor, results in a lower threshold voltage of the circuit, or a transistor. So, as the temperature of a circuit comprising MOSFETs increases, both the mobility and the threshold voltage of the circuit are reduced. Changes in the threshold voltage and the mobility affect the value of the on-current in a circuit comprising MOSFETs.

Overall, as outlined above, the effect of increasing temperature on the on-current is dictated by the particular supply voltage applied to the circuit. At levels of the supply voltage above the ZTC voltage, the overall effect of increasing temperature on the on-current will be to reduce the on-current of the circuit, or individual MOSFET. However, at levels of supply voltage below the ZTC voltage, the overall effect of increasing temperature on the on-current will be to increase the on-current of the circuit, or individual MOSFET.

In contrast, however, the effect that temperature has on the subthreshold drain current does not depend on the supply voltage to a particular MOSFET. Indeed, it is known, and can be shown, that the subthreshold drain current of a particular MOSFET is a function of temperature and will increase with increasing temperature regardless of the supply voltage.

The Delay of a Circuit Decreases with Increasing Temperature

Another observation that may be made is that the delay of a circuit comprised of MOSFET type transistors decreases as the temperature of the circuit increases. The delay of a circuit reflects how fast a circuit can switch its output. The switching of output generally involves the charging or discharging of the load capacitance of the circuit.

The gate delay is a function of the drain current, the supply voltage and the load capacitance. This relationship can be shown mathematically as:

$$Delay \approx \frac{{C}_{L} {V}_{dd}}{{I}_{DSAT}} , \qquad ( 7 )$$

where C_{L} is the load capacitance and I_{DSAT} is the drain saturation-current, or “on-current.”

As explained above, for supply voltages below the ZTC voltage, it has been observed that as the temperature of a circuit increases, the on-current of the circuit also increases. Therefore, based on the above relationship, as the on-current increases with increasing temperature, the gate delay of the circuit decreases. Generally, the load capacitance and the supply voltage do not change with changing temperature.

Hence, the lowest on-current, which results in the “worst-case” gate delay, occurs at the lowest operating temperature of the circuit. The gate delay is reduced and the leakage power is increased by increasing the temperature. Therefore, the “worst-case” static power consumption of a circuit is at the maximum operating temperature of the circuit, while the “worst-case” delay of the same circuit is at the minimum operating temperature of the circuit.

The Preferred Embodiment of the Power Control System and Method

Recognizing the above features and qualities of digital circuits relating to changing temperature of the circuit, the present systems and methods are directed to adjusting the supply voltage of a circuit as the temperature of the circuit changes. Preferably, the adjustment to the power supply voltage is performed in such a manner that the delay of the circuit becomes independent of the circuit temperature. That is, the delay is preferably held constant, or nearly constant, by decreasing the power supply voltage as the temperature of the circuit increases. The product of decreasing the supply voltage will, of course, be to decrease the subthreshold current, which will, in turn, decrease the static power consumption. In addition, the reduction in the supply voltage will decrease the dynamic power consumption and the short circuit power consumption of the circuit. Preferably, this preferred embodiment is implemented with a circuit that is operating with a supply voltage less than the ZTC voltage of the MOSFET.

On a general level, the first step of the preferred method is to detect a temperature change in the circuit. Then, as the temperature changes, then next step in the preferred method is to change the supply voltage to the circuit in response to the temperature change such that the delay of the circuit is held constant and, as a result, the power consumption of the circuit is reduced.

A change in the temperature of the circuit can be detected in a number of ways. Of course, the temperature can be monitored directly. On the other hand, other values or characteristics of the circuit may be monitored in order to detect a change in temperature. In other words, temperature may be monitored indirectly.

The method of reducing circuit power consumption will preferably be implemented by some control structure. The control structure may, for example, comprise a control circuit or other control hardware, among many other possibilities. The control circuit will detect the changing temperature of the circuit, and, responsive to this temperature change, will adjust the supply voltage to the circuit. As will be noted below, the control circuit may also be employed with a timing device.

First Preferred Embodiment Implemented by Monitoring Delay

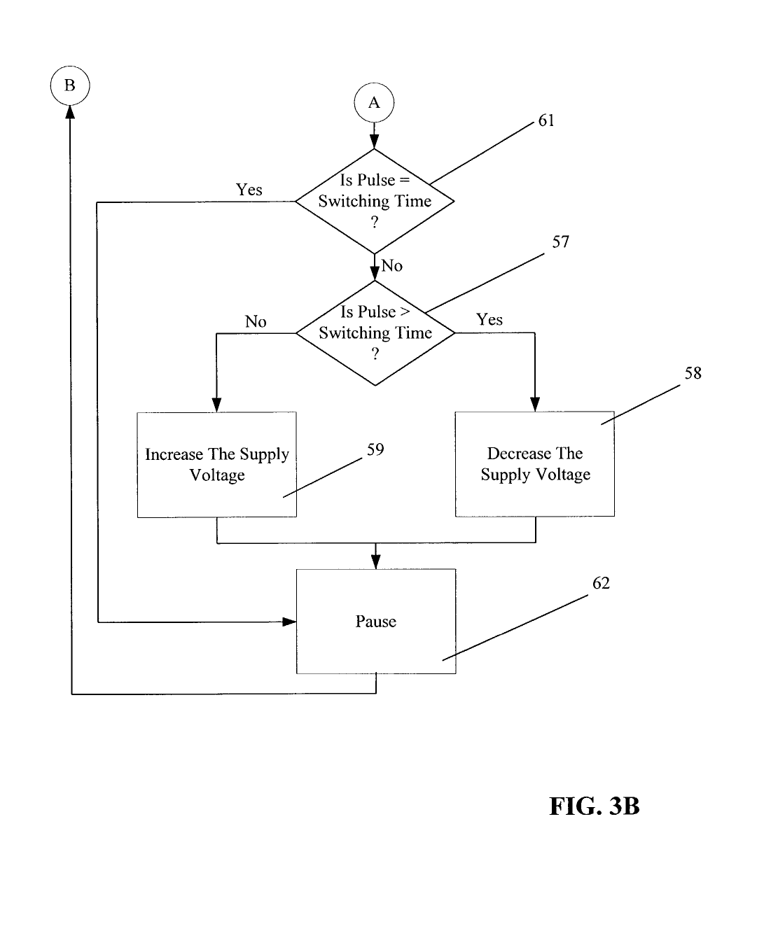

The steps of the first preferred embodiment 50 of the disclosed method are demonstrated in FIG. 3A and FIG. 3B. The depicted and described method will preferably be implemented by a control device, such as a control circuit. The control device may be a separate control circuit specifically designed for the purpose of implementing the preferred method, or it may be a portion of a larger circuit that may, for example, accomplish other tasks. The actual implementation of the control circuit is not critical to the preferred method.

The control circuit preferably has a system for measuring the delay of the circuit. As delay is a function of circuit temperature, measuring the delay is an indirect measurement of the temperature of the circuit. This measuring system may be a part of the control circuit, or may simply be associated with the control circuit. In the first preferred embodiment, the control circuit has an apparatus that will issue an electronic pulse of a set length and monitor the pulse. This pulse mechanism can be used to measure time.

The control circuit of the first preferred embodiment also includes a series of test gates built into the same substrate as the circuit to be controlled. This series of test gates can be of any type. For example, the gates may comprise a series of “NOT gates,” a series of “AND gates,” or most preferably, a mixture of different types of logic gates.

These test gates will be used by the control circuit to monitor the delay of the circuit to be controlled in an indirect manner. A series of gates is preferably used by the control circuit because it is easier to measure the delay of a series of gates. The delay of a typical single gate is usually quite small. It is, therefore, more difficult to measure the very small delay of a single gate.

The first step in the preferred method, as shown in FIG. 3A, is to compute the “worst-case” delay of the test gates (Block 51). As noted above, the “worst-case” delay of a circuit is the delay of the circuit at the minimum operating temperature of the circuit. The minimum operating temperature of the test gate circuit is known by the manufacturer of the circuit based on the particular characteristics of the circuit. One with ordinary skill in the art can easily determine the minimum operating temperature of the test gate circuit.

The actual computation of the “worst-case” delay can be accomplished by the control circuit by reference to look-up table, database, or by computation based on a functional relationship between the temperature of the circuit and the delay. On the other hand, the “worst-case” delay could be computed by another device, such as for example, based on experimentation with the test gates or simulation, and this value stored in a memory register.

The control circuit sets the length of the electrical pulse equal to the value of the “worst-case” delay of the circuit (Block 52).

The next two steps (Blocks 53 and 54) of the preferred method are implemented at the same time by the control circuit. The control circuit issues an electronic pulse of a known duration (Block 53). The duration of the pulse, as noted just above, is set to be equivalent to the length of the “worst-case” delay of the test gate circuit.

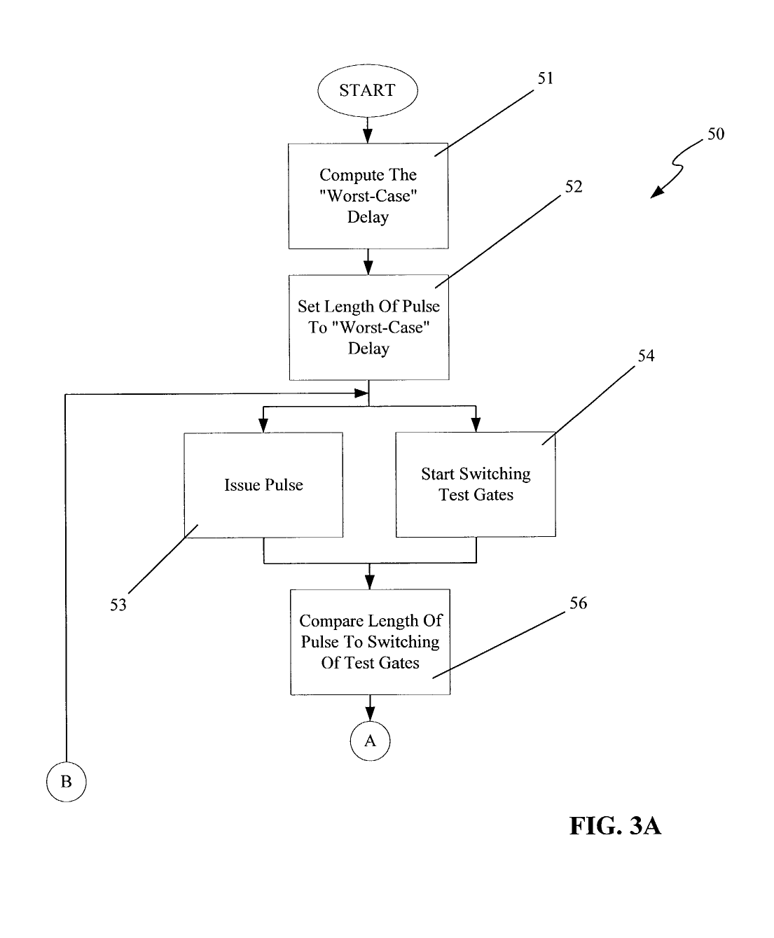

At the same time the pulse is started, the control circuit begins switching the test gates (Block 54). For example, the gate voltage of the first gate is changed from a low value (zero) to a high value (one). Of course, this effectively switches the output of the gate. For example, if the first gate is a “NOT gate,” such as the gate depicted in FIG. 2, then the NFET of the first test gate is switched from an “off” configuration, to an “on” configuration and the PFET of the first test gate is switched from an “on” configuration, to an “off” configuration. Thus, in this example, the “output” voltage of the first gate will be switched from an initial value of high voltage to a low voltage. From a digital perspective, the input will be switched from a zero to a one, and the output of the first test gate will be switched from a one to a zero.

The output of this first gate will affect the second gate and cause the second gate to also switch its output. Similarly, the change in the output of the second gate will affect the third gate, and so on until the last test gate is reached.

The control circuit monitors the electronic pulse and the switching of the test gates. The control circuit preferably compares when the pulse ends to when the last gate in the test gates switches output (Block 56).

As shown in FIG. 3B, the circuit first tests for the rare case in which the length of the pulse is equivalent to the switching time, or delay, of the test gates (Block 61). If the two times are not equal, then the control circuit determines which finished first (Block 57). If the pulse finished first, this means that the delay of the test gates is greater than the “worst-case” delay (Block 57). Of course, if the last gate switched output prior to the completion of the pulse, then the delay of the test gates is less than the “worst-case” delay (Block 57).

A change to the delay of the test gates reflects a change to the delay of the overall circuit to be controlled. In the first embodiment, it is the goal of the method to maintain the delay of the test gates equivalent to the “worst-case” delay of the test gates. This will, likewise, maintain the delay of the overall circuit to be controlled at a relatively high level, near or at the “worst-case” delay of the overall circuit. Therefore, if the delay of the test gates decreases, as will happen with increasing circuit temperature, the supply voltages of the MOSFETs that make up the circuit to be controlled and the MOSFETs that make up the test gates are adjusted (Block 58).

In order to maintain the delay at or near the “worst-case” delay, if the pulse finishes later than the time when the last gate is switched, the control circuit decreases a supply voltage to the circuit (Block 58). Of course, a decrease in delay means that the temperature of the circuit has increased. Decreasing the supply voltage to the circuit will increase the delay back toward the “worst-case” delay and also serve to reduce the power consumption of the circuit.

The supply voltage can be adjusted according to a relationship to the change in delay. For example, for a decrease in delay of a certain amount, the supply voltage to the circuit may be decreased by a corresponding amount. Such a relationship can be implemented by an equation, in a look-up table, a database, or the like. However, it is much simpler, and preferable, to merely change the supply voltage by a set amount if the delay has changed at all. For example, in the preferred embodiment, the supply voltage will be changed by 0.01 Volt for every change in the delay of the test gate circuit.

Of course, if the last gate switches after the pulse has finished, this means that the temperature of the circuit has decreased, and that the delay has increased to a value greater than the “worst-case” delay. Therefore, the control circuit increases the supply voltage to the circuit (Block 59).

Once the adjustment to the supply voltage is implemented, if any adjustment is made, the control circuit preferably pauses for a predetermined period, e.g., approximately 1-2 seconds (Block 62). Then, the process may begin again with issuing the electrical pulse (Block 53) and switching the gates of the test gate circuit (Block 54).

The method described above is only one possible way of measuring the delay of the circuit to be controlled. In essence the described method indirectly measures the delay of the circuit to be controlled by using a series of test gates. As another possible implementation, the control circuit can be configured to measure the delay of the entire circuit to be controlled directly. The control circuit, on the other hand, could measure the delay of only a portion of the circuit to be controlled. In such a case, the delay of the circuit to be controlled would be directly measured by the control circuit.

The temperature of the circuit will likely increase over time from an initial temperature to a normal operating temperature. The above-described first embodiment adjusts the supply voltage to the circuit as the temperature of the circuit increases. This, in turn, results in the same “worst-case” delay while a reduction in both the static, dynamic, and short circuit power consumption of the circuit.

Second Preferred Embodiment Implemented by Monitoring Temperature

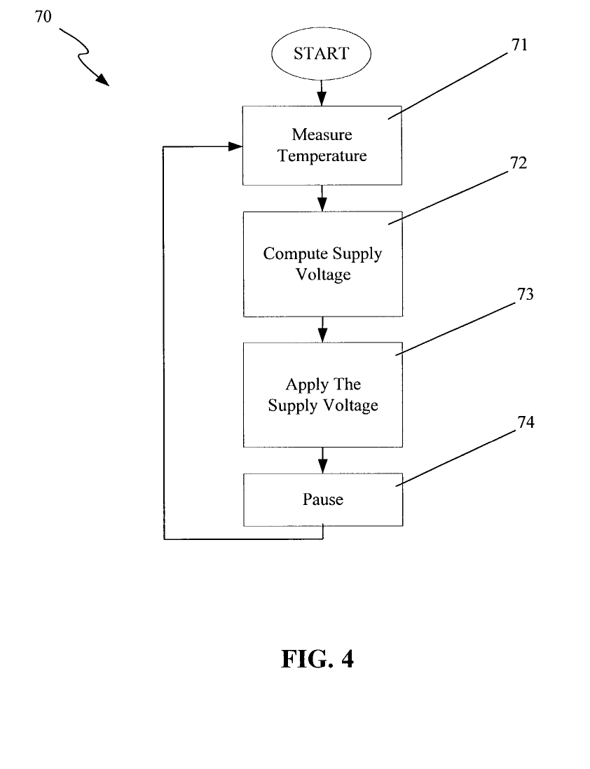

Reduction of circuit power consumption through reduction in the supply voltage can also be implemented by monitoring the temperature of the circuit to be controlled directly. For example, FIG. 4 depicts the steps involved for this implementation of the second preferred embodiment 70. As with the first preferred embodiment, the preferred method 70 is implemented by a control circuit for reducing static power consumption of the circuit.

In this embodiment 70, the first step is to measure the temperature of the circuit (Block 71). The temperature of the circuit is typically measured by a temperature sensor. Any temperature sensor can be used by the control circuit. However, the temperature sensor preferably takes the form of a sensor located on the semiconductor.

After measuring the temperature (Block 71), the control circuit computes the appropriate supply voltage value to apply to the circuit (Block 72). The amount of the supply voltage can be computed from an awareness of the particular characteristics of the specific circuit involved. On the other hand, in the preferred embodiment, the control circuit refers to a look-up table or other data structure to arrive at an appropriate supply voltage for a given temperature of the circuit. The look-up table may be generated by simulations of the circuit, or actual test data from the circuit.

In this second preferred embodiment, the method and apparatus should maintain the delay of the circuit at a constant value equivalent to the “worst-case” delay of the circuit. Delay is a function of temperature. As the temperature of the circuit increases, the delay of the circuit decreases. Conversely, as the temperature of the circuit decreases, the delay of the circuit increases. So, in this second preferred embodiment, the supply voltage is computed such that at the measured temperature, the delay of the circuit will be the “worst-case” delay of the circuit.

Once the new supply voltage is computed, the control circuit implements the supply voltage (Block 73). Generally, if the temperature of the circuit is greater than the lowest operating temperature of the circuit, the supply voltage to the circuit will be decreased in order to hold the delay of the circuit at a steady, “worst-case” level.

Once the supply voltage is adjusted, the control circuit preferably waits for a specified period of time before taking another temperature measurement (Block 74). After a period of time has elapsed, the entire process 70 begins again. The pause (Block 74) may be on the order of 1-2 seconds. Of course, the measurement, and corresponding adjustment process could be continuous.

Graphical Representations of the Results of the Preferred Embodiments

As noted above, the preferred method of determining a temperature increase involves monitoring the delay of the circuit. Then, the preferred control circuit maintains a constant delay for the circuit by adjusting the supply voltage to the circuit.

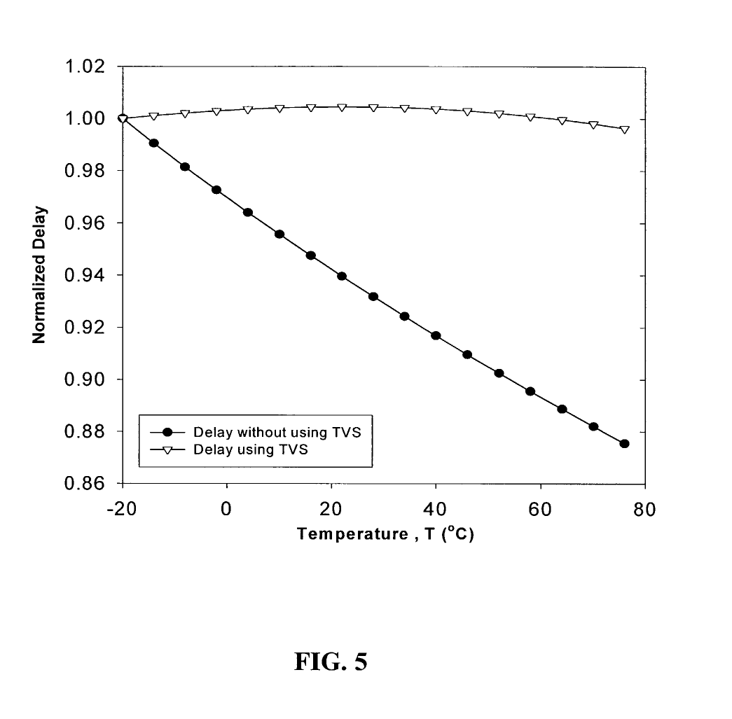

FIG. 5 graphically shows the normalized delay versus temperature for an exemplary 70 nm MOSFET using the preferred method described above. In FIG. 5, the preferred method is referred to as “TVS” (Temperature Variable Supply voltage). FIG. 5 demonstrates that when the preferred TVS method described above is used, the delay is maintained at a constant value. This delay is known as the “worst-case” delay.

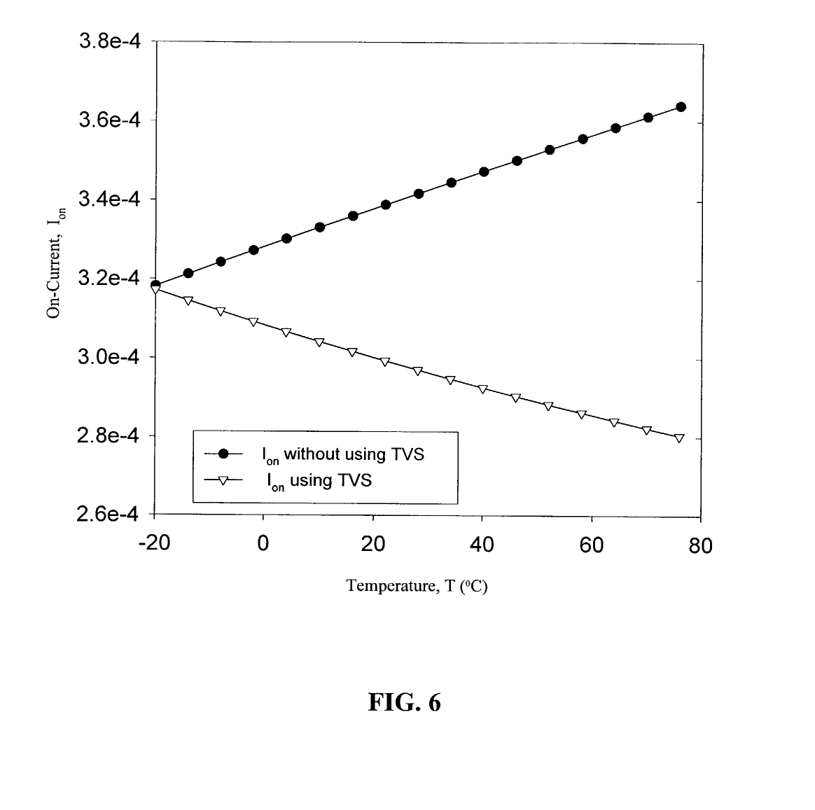

On the other hand, FIG. 6 shows the saturation-current versus the temperature for an exemplary 70 nm CMOS circuit. As shown in FIG. 6, using the above-described preferred TVC technique results in on-current reduction versus temperature.

As the supply voltage is reduced, the dynamic power dissipation, is also reduced. Dynamic power can be expressed as:

P_{dy}=α·C·V_{dd}²·ƒ, (14)

where α is an activity factor for the output node and is related to the probability for the signal to charge and discharge the capacitor during a clock cycle. Furthermore, the variable C is the capacitance of the output node, V_{dd} is the supply voltage and ƒ is the clock frequency.

While the dynamic power consumption is reduced, the “worst-case” delay of the circuit does not change because, as shown in FIG. 5, the delay versus temperature is constant and equal to the “worst-case” delay. The reduction in the dynamic power reduces the total power consumption, which as a result, reduces the chip temperature. Reduction in the temperature reduces the subthreshold leakage current.

Reducing the supply voltage reduces what is known as the Drain Induced Barrier Lowering (“DIBL”) effect, which will increase the threshold voltage. Of course, an increase in the threshold voltage reduces the leakage current. Both the supply voltage and the subthreshold current are decreasing, therefore the static power, which is calculated by equation 3 above, will decrease.

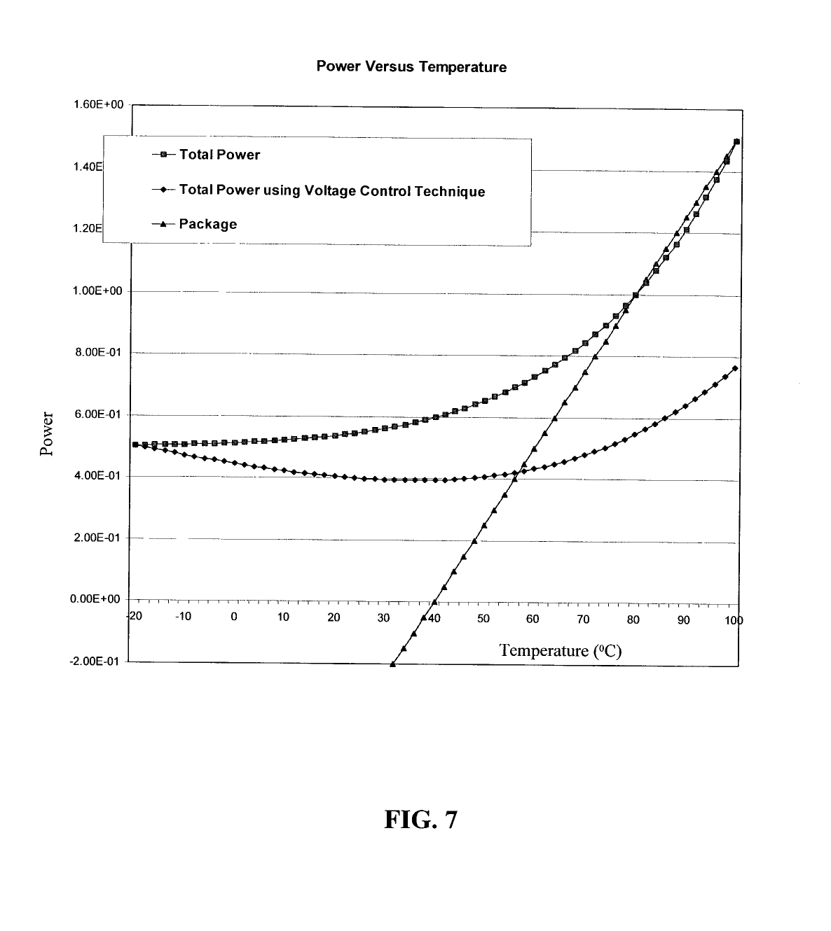

FIG. 7 is a plot of normalized total power consumption of an exemplary 70 nm CMOS circuit with and without the preferred method described herein, as a function of temperature. When the method disclosed above is not used, the dynamic power is not a function of temperature. However, the static power increases as the temperature rises. As a result, the total power increases as the temperature is increased.

FIG. 7 also shows the power-transferred by the IC chip, or “package,” to the ambient versus the temperature. The point where the total power dissipation curve of the IC chip intersects the power-transfer curve by the package gives the steady state power dissipation and also the temperature of the chip. When the preferred TVS method is used, the total power is reduced as the temperature increases. Therefore, the IC chip dissipates less power and works at a lower temperature.

As shown in FIG. 7, when the TVS method is used, the total power is reduced by 24% and the IC chip temperature is reduced from 80° C. to almost 70° C. As a result of using this technique the dynamic and static power are reduced by 22% and 40%, respectively. If this technique is used for even smaller than 70 nm transistors with lower supply voltages it will result in even more power reduction.

It should be understood that the above-described plots are only examples of the results possible with a particular circuit and a particular implementation of the preferred apparatus and method. The preferred system and method are not limited to results in any particular range.

Use of the Preferred Method with Multiple Threshold Voltage Circuits

Multiple threshold voltage circuits are gaining more popularity with integrated circuit designers. In these types of integrated circuits or other types of chips, transistors having different threshold voltages are incorporated into the same IC chip. The theory of the design typically is to use low threshold voltage transistors in a critical path and high threshold voltage transistors in the remainder of the circuit.

Typically, only a small portion of the circuit comprises a critical path. Therefore, most of the circuit is built of high threshold voltage transistors, which will result in low leakage current and low static power dissipation. As temperature is increased, threshold voltage is decreased, which will result in higher switching current or lower delay. The larger the threshold voltage is, the higher the percentage change in switching current will be. Therefore, circuits with higher threshold voltage are more sensitive to temperature and as a result the systems and methods as described above will likely be more effective for them.

In multiple voltage threshold circuits, most of the circuit is made of high threshold voltage transistors therefore high power reduction could be achieved through using the preferred system and method for multiple threshold voltage circuits.

Partitioning the Integrated Circuit Chip

In the typical embodiment of an integrated circuit (“IC”) chip having many transistors on the chip, different parts of the chip may consume and dissipate different amounts of power. For this reason, the temperatures of different parts of the chip may be different. Obviously, the method disclosed herein depends on the temperature of the circuit to change the static power consumption. For this reason, it may be desirable to divide the chip into different units.

In essence, the IC chip can be divided into blocks and the preferred system and method can be applied to each block separately. Because the technique, and responsive reduction in supply voltage, may be tailored to different temperature regions, the power consumption of the overall IC chip can be reduced even more by partitioning the chip and treating different groups of transistors separately. As a result of using this partitioning technique, different parts of the chip will have different supply voltages. Therefore, a circuit such as a “level-shifter” may be needed to connect the blocks with different voltages to each other.

It should be emphasized that the above-described embodiments of the present invention, particularly, any “preferred” embodiments, are merely possible examples of implementations, merely set forth for a clear understanding of the principles of the invention. Many variations and modifications may be made to the above-described embodiment(s) of the invention without departing substantially from the spirit and principles of the invention. All such modifications and variations are intended to be included herein within the scope of this disclosure and the present invention and protected by the following claims.

Therefore, having thus described the invention, at least the following is claimed:

1. A method for controlling the power consumption of a circuit, comprising:
detecting a temperature change at the circuit; and
adjusting a supply voltage to the circuit such that the power consumption is reduced.

2. The method of claim 1, wherein said detecting step comprises:
measuring a delay of the circuit;
comparing said measured delay of the circuit to a worst-case delay for the circuit, wherein if said measured delay is less than said worst-case delay, then the temperature at the circuit has increased.

3. The method of claim 2, wherein said adjusting step comprises changing said supply voltage to the circuit such that said measured delay of said circuit is made to equal said worst-case delay.

4. The method of claim 3, wherein said circuit has a supply voltage below a Zero Temperature Coefficient voltage for a MOSFET in said circuit.

5. The method of claim 3, wherein said worst-case delay comprises the delay of the circuit at a minimum operating temperature of the circuit.

6. A method for controlling the power consumption of a circuit, comprising:
measuring a delay of the circuit;
adjusting a supply voltage to the circuit such that said delay is maintained at a substantially constant value.

7. The method of claim 6, wherein said substantially constant value comprises a delay for the circuit at a minimum operating temperature of the circuit.

8. The method of claim 7, wherein said circuit has a supply voltage below a Zero Temperature Coefficient voltage for a MOSFET in said circuit.

9. A system for controlling power consumption by a circuit, comprising:
means for detecting a temperature change at the circuit;
means for adjusting a supply voltage to a circuit responsive to said temperature change at the circuit.

10. The system of claim 9, wherein said means for detecting comprises a control circuit that measures a delay of the circuit and compares said delay to a worst-case delay for the circuit.

11. The system of claim 10, wherein said means for adjusting comprises a control circuit that changes the supply voltage to the circuit if said delay of the circuit is less than the worst-case delay of the circuit such that said delay is made to substantially equal the worst-case delay of the circuit.

12. The system of claim 11, wherein said worst-case delay comprises a delay of the circuit at a minimum operating temperature of the circuit.

13. A method for reducing total power consumption of a circuit, comprising:
providing a gate;
providing a control circuit for said gate; and
adjusting a supply voltage to said gate such that said gate maintains a substantially constant delay for the circuit.

14. The method of claim 13, wherein said gate is a circuit comprised of at least one MOSFET.

15. The method of claim 14, wherein said supply voltage is not greater than a Zero Temperature Coefficient voltage of said at least one MOSFET.

16. The method of claim 15, wherein said substantially constant delay of said circuit is substantially equivalent to a worst-case-delay of said circuit.

17. A system for reducing the power dissipation, comprising:
an integrated circuit chip having a plurality of transistors;
a control circuit for reducing power consumed by said integrated circuit chip by adjusting a power supply voltage to said integrated circuit chip.

18. The system of claim 17, wherein said integrated circuit chip is partitioned into a plurality of regions.

19. The system of claim 18, wherein said control circuit reduces the power consumed by said integrated circuit by adjusting the power supply voltage to at least one of said regions of said integrated circuit chip responsive to a change in a temperature at one of said regions of said integrated circuit chip.

20. The system of claim 19, wherein said control circuit comprises a sensor thermally coupled to said integrated circuit chip.
